(19) United States
(12) Patent Application Publication
(10) Pub. No.: US 2026/0100217 A1
(43) Pub. Date: Apr. 9, 2026

(54) CLOCK SIGNAL GATING CIRCUIT

(71) Applicant: Winbond Electronics Corp., Taichung City (TW)

(72) Inventor: Che-Min Lin, Taipei (TW)

(73) Assignee: Winbond Electronics Corp., Taichung City (TW)

(21) Appl. No.: 19/333,336

(22) Filed: Sep. 18, 2025

(30) Foreign Application Priority Data
Oct. 9, 2024 (TW) 113138506

(51) Int. Cl. G11C 11/4076; H03K 3/037; H03K 19/21

(52) U.S. Cl. CPC G11C 11/4076; H03K 3/037; H03K 19/21

(57) ABSTRACT

A clock signal gating circuit including a clock signal input buffer, a first logic circuit, a second logic circuit, and a latch circuit is provided. The clock signal input buffer receives a clock signal and outputs an internal clock signal based on a clock switch signal. The first logic circuit receives an asynchronous clock enable signal and a synchronous clock enable signal and outputs the clock switch signal. The second logic circuit receives the asynchronous clock enable signal, the synchronous clock enable signal, and the internal clock signal and outputs a clock gating signal. The latch circuit receives the asynchronous clock enable signal and the clock gating signal to output the synchronous clock enable signal.

### CROSS-REFERENCE TO RELATED APPLICATION

This application claims the priority benefit of Taiwan application serial no. 113138506, filed on October 9, 2024. The entirety of the above-mentioned patent application is hereby incorporated by reference herein and made a part of this specification.

### BACKGROUND

### Technical Field

The disclosure relates to a clock control technology, and particularly relates to a clock signal gating circuit.

### Description of Related Art

A clock enable (CKE) signal in memory devices such as DRAM serves to switch on or off a clock signal input buffer. FIG. 1 illustrates a control circuit of a conventional clock signal input buffer. As shown in FIG. 1, a clock signal input buffer 14 receives a pair of complementary clock signals CLK_T and CLK_C and outputs an internal clock signal CK_t. An input buffer 10 receives a clock enable signal CKE and a reference voltage signal VREF and generates an asynchronous clock enable signal CKE_ASYNC accordingly. Besides, a latch circuit 12 receives the asynchronous clock enable signal CKE_ASYNC and the internal clock signal CK_t, thereby generating a synchronous clock enable signal CKE_SYNC.

As such, the clock enable signal CKE in a circuit is divided into the asynchronous clock enable signal CKE_ASYNC and the synchronous clock enable signal CKE_SYNC, which are then combined through an OR gate 16 to produce a clock switch signal CLK_EN for the clock signal input buffer. According to the related art, the synchronous clock enable signal CKE_SYNC remains active when the clock enable signal CKE is at a high level. As a result, even in a standby mode, the overall circuit continues to consume power. Consequently, identifying strategies to mitigate this power consumption has emerged as a significant concern.

### SUMMARY

According to an embodiment of the disclosure, a clock signal gating circuit including a clock signal input buffer, a first logic circuit, a second logic circuit, and a latch circuit is provided. The clock signal input buffer receives a clock signal and outputs an internal clock signal based on a clock switch signal. The first logic circuit receives an asynchronous clock enable signal and a synchronous clock enable signal and outputs the clock switch signal. The second logic circuit receives the asynchronous clock enable signal, the synchronous clock enable signal, and the internal clock signal and outputs a clock gating signal. The latch circuit receives the asynchronous clock enable signal and the clock gating signal to output the synchronous clock enable signal.

In light of the foregoing, through the second logic circuit, the synchronous clock enable signal may not remain active when the clock enable signal is at a high level, thereby reducing power consumption of the overall circuit even in a standby mode.

### BRIEF DESCRIPTION OF THE DRAWINGS

FIG. 1 illustrates a control circuit of a conventional clock signal input buffer.

FIG. 2 illustrates a clock signal gating circuit according to an embodiment of the disclosure.

FIG. 3 is an operation timing diagram illustrating a clock signal gating circuit according to an embodiment of the disclosure.

### DESCRIPTION OF THE EMBODIMENTS

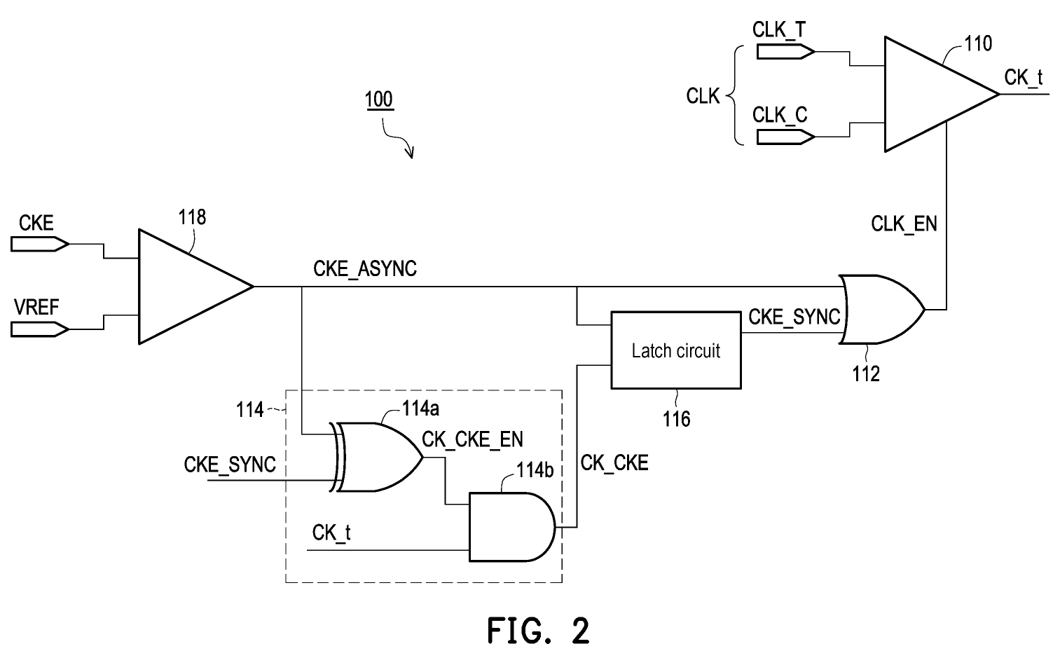

FIG. 2 illustrates a clock signal gating circuit according to an embodiment of the disclosure. This clock signal gating circuit 100 may be applied in a memory device, such as a dynamic random access memory (DRAM) or any other type of memory device. Besides, when the memory device is a DRAM, the DRAM may, for instance, comply with double data rate (DDR) specifications.

As shown in FIG. 2, the clock signal gating circuit 100 includes at least one clock signal input buffer 110, a first logic circuit 112, a second logic circuit 114, and a latch circuit 116. The clock signal gating circuit 100 may further include an input buffer 118.

The input buffer 118 is designed to receive a clock enable signal CKE and a reference voltage signal VREF and output an asynchronous clock enable signal CKE_ASYNC based on these inputs. In other words, the input buffer 110 may convert the clock enable signal CKE and output the asynchronous clock enable signal CKE_ASYNC depending on whether the signal level of the reference voltage signal VREF is high or low. The asynchronous clock enable signal CKE_ASYNC may be used to activate the clock signal input buffer 110.

The clock signal input buffer 110 is designed to receive a clock signal CLK and output an internal clock signal CK_t based on a clock switch signal CLK_EN. In other words, the clock input buffer 110 receives the externally input clock signal CLK and outputs the internal clock signal CK_t for various internal operations of the memory device. In an exemplary embodiment, the clock signal CLK may include a pair of complementary clock signals CLK_T and CLK_C (as exemplarily shown in FIG. 2). The clock input buffer 110 is subject to the clock switch signal CLK_EN output from the first logic circuit 112 to activate or deactivate the clock input buffer 110.

The first logic circuit 112 is designed to receive the asynchronous clock enable signal CKE_ASYNC and a synchronous clock enable signal CKE_SYNC and output the clock switch signal CLK_EN. The clock switch signal CLK_EN is further provided to the clock input buffer 110 to activate or deactivate the clock input buffer 110. Here, in an exemplary embodiment, the first logic circuit 112 may be constituted by an OR gate, or may be a combination of various other logic gates capable of performing the same logic operation.

Generally, after the clock enable signal CKE is received from an external source, the clock enable signal CKE is divided into two paths: the path for the asynchronous clock enable signal CKE_ASYNC and the path for the synchronous clock enable signal CKE_SYNC. The asynchronous clock enable signal CKE_ASYNC and the synchronous clock enable signal CKE_SYNC subsequently generate the clock switch signal CLK_EN through the first logic circuit 112.

When the clock enable signal CKE transitions to a high level, the output asynchronous clock enable signal CKE_ASYNC activates the clock signal input buffer 110, causing the clock signal input buffer 110 to output the internal clock signal CK_t. Upon the transition of the clock enable signal CKE to a low level, the synchronous clock enable signal CKE_SYNC is generated through the latch circuit 116, with a delay by a predetermined number of clock cycles. The synchronous clock enable signal CKE_SYNC may deactivate the clock signal input buffer 110, resulting in the cessation of the output of the internal clock signal CK_t.

The second logic circuit 114 is designed to receive the asynchronous clock enable signal CKE_ASYNC, the synchronous clock enable signal CKE_SYNC, and the internal clock signal CK_t, and to output a clock gating signal CK_CKE. Furthermore, when the asynchronous clock enable signal CKE_ASYNC and the synchronous clock enable signal CKE_SYNC are in different phases, an output signal CK_CKE_EN transitions to a high level. During the period when the output signal CK_CKE_EN is at a high level, the clock gating signal CK_CKE is output. The clock gating signal CK_CKE is subsequently provided to the latch circuit 116.

In addition, according to an embodiment of the disclosure, the second logic circuit 114 may further include a phase comparison circuit 114a and a switch 114b. The phase comparison circuit 114a receives and compares a phase of the asynchronous clock enable signal CKE_ASYNC and a phase of the synchronous clock enable signal CKE_SYNC, and when the phases are different, the output signal CK_CKE_EN of the phase comparison circuit 114a transitions to a high level. The switch 114b receives the output signal CK_CKE_EN from the phase comparison circuit 114a and the internal clock signal CK_t and outputs the clock gating signal CK_CKE.

In an embodiment of the disclosure, the phase comparison circuit 114a may be constituted by an XOR gate (hereinafter referred to as the XOR gate 114a), while the switch may be constituted by an AND gate (hereinafter referred to as the AND gate 114b). Here, both the XOR gate 114a and the AND gate 114b may be replaced with various combinations of other logic gates that may achieve the same logical operation.

The latch circuit 116 is designed to receive the asynchronous clock enable signal CKE_ASYNC and the clock gating signal CK_CKE and output the synchronous clock enable signal CKE_SYNC. In other words, the asynchronous clock enable signal CKE_ASYNC from the input buffer 118 is further input to the latch circuit 116. The latch circuit 116 further receives the clock gating signal CK_CKE output from the second logic circuit 114 and accordingly outputs the synchronous clock enable signal CKE_SYNC. The latch circuit 116 may, based on the asynchronous clock enable signal CKE_ASYNC and the clock gating signal CK_CKE, delay the asynchronous clock enable signal CKE_ASYNC by a predetermined number of clock cycles to generate the synchronous clock enable signal CKE_SYNC.

An operation method of the second logic circuit 114 is explained hereinafter. In an exemplary embodiment, the phase comparison circuit 114a may be constituted by an XOR gate, while the switch 114b may be constituted by an AND gate. As shown in FIG. 2, the XOR gate 114a receives the asynchronous clock enable signal CKE_ASYNC and the synchronous clock enable signal CKE_SYNC. Through the XOR gate 114a, only when the asynchronous clock enable signal CKE_ASYNC and the synchronous clock enable signal CKE_SYNC are either in different phases (inverted) or at different levels, the output signal CK_CKE_EN of the XOR gate 114a transitions to a high level.

Subsequently, the output signal CK_CKE_EN is further provided to the AND gate 114b. The AND gate 114b receives the output signal CK_CKE_EN and the internal clock signal CK_t from the clock signal input buffer 110 and accordingly outputs the clock switch signal CK_CKE. Here, when the output signal CK_CKE_EN is at a high level, the AND gate 114b may output the clock gating signal CK_CKE, which is the same as the internal clock signal CK_t, to the latch circuit 116. Conversely, when the output signal CK_CKE_EN is at a low level, the output of the clock gating signal CK_CKE to the latch circuit 116 is halted. Consequently, the AND gate 114b may be regarded as a clock path that provides the internal clock signal CK_t to the latch circuit 116 based on the state of the output signal CK_CKE_EN.

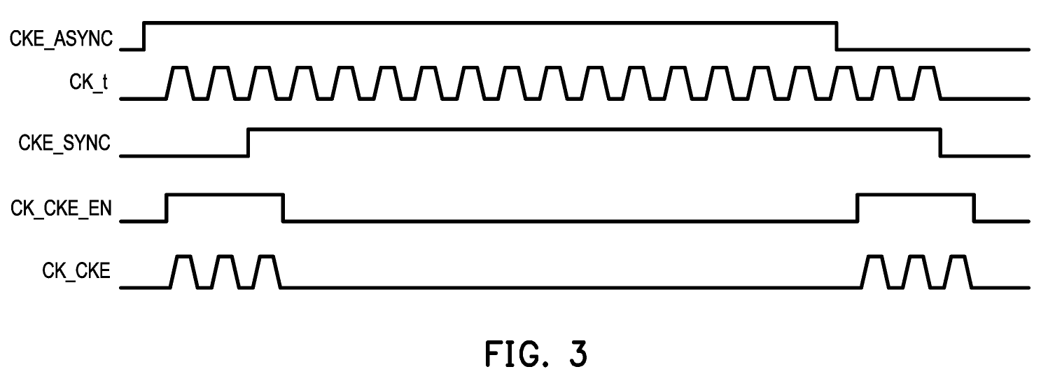

FIG. 3 is an operation timing diagram illustrating a clock signal gating circuit according to an embodiment of the disclosure. With reference to FIG. 3, first, when the asynchronous clock enable signal CKE_ASYNC changes from a low level to a high level, since the synchronous clock enable signal CKE_SYNC is at a low level, the output signal CLK_CKE_EN of the XOR gate 114a transitions to a high level. Then, the AND gate 114b generates the clock gating signal CK_CKE, which is the same as the internal clock signal CK_t, and transmits the clock gating signal CK_CKE to the latch circuit 116. The latch circuit 116 then re-latches the high-level asynchronous clock enable signal CKE_ASYNC according to the clock gating signal CK_CKE and accordingly generates the high-level synchronous clock enable signal CKE_SYNC. Afterwards, the synchronous clock enable signal CKE_SYNC remains at a high level.

At this time, as shown in FIG. 3, since both the asynchronous clock enable signal CKE_ASYNC and the synchronous clock enable signal CKE_SYNC are at high levels, the output signal CLK_CKE_EN of the XOR gate 114a transitions to a low level, and the AND gate 114b stops generating the clock gating signal CK_CKE.

On the other hand, when the asynchronous clock enable signal CKE_ASYNC transitions from a high level to a low level, since the synchronous clock enable signal CKE_SYNC is at a high level, the output signal CLK_CKE_EN of the XOR gate 114a transitions to a high level. Then, the AND gate 114b generates the clock gating signal CK_CKE, which is the same as the internal clock signal CK_t, and transmits the clock gating signal CK_CKE to the latch circuit 116. The latch circuit 116 then re-latches the low-level asynchronous clock enable signal CKE_ASYNC according to the clock gating signal CK_CKE and accordingly generates the low-level synchronous clock enable signal CKE_SYNC. Afterwards, the synchronous clock enable signal CKE_SYNC remains at a low level.

At this time, as shown in FIG. 3, since both the asynchronous clock enable signal CKE_ASYNC and the synchronous clock enable signal CKE_SYNC are at low levels, the output signal CLK_CKE_EN of the XOR gate 114a transitions to a low level, and the AND gate 114b stops generating the clock gating signal CK_CKE.

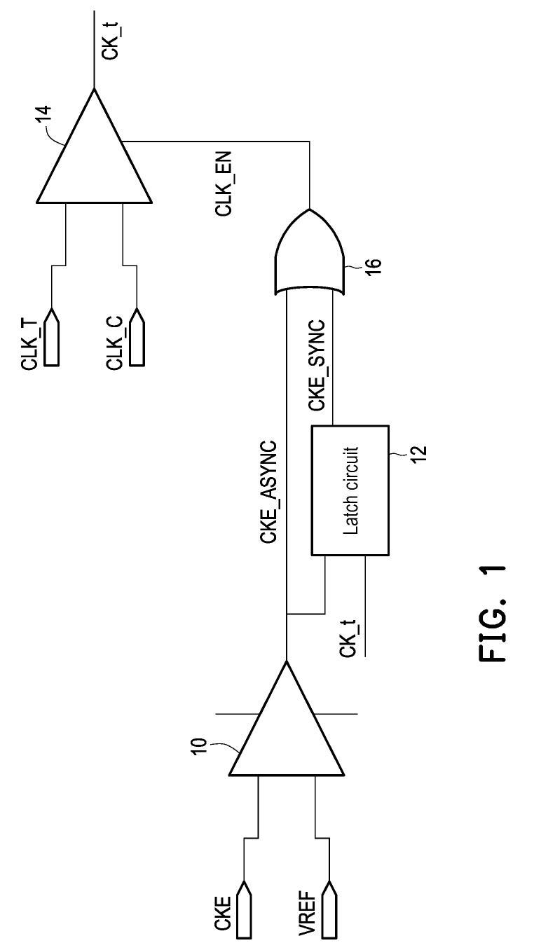

Consequently, this circuit architecture allows the latch circuit 116 to retain the state of the synchronous clock enable signal CKE_SYNC during a standby mode, while the clock gating signal CK_CKE, which controls the latch circuit 116 to re-latch the asynchronous clock enable signal CKE_ASYNC, transitions to and remains at a low level to prevent the latch circuit 116 from re-latching the asynchronous clock enable signal CKE_ASYNC, thereby reducing power consumption. The clock gating signal CK_CKE is only regenerated when the synchronous clock enable signal CKE_SYNC and the asynchronous clock enable signal CKE_ASYNC are in different phases, prompting the latch circuit 116 to re-latch the asynchronous clock enable signal CKE_ASYNC. Compared to the exemplary embodiment depicted in FIG. 1, the internal clock signal CK_t is continuously supplied to the latch circuit 12 even in a standby mode, resulting in persistent latching of the asynchronous clock enable signal CKE_ASYNC by the latch circuit 12. Therefore, according to one or more embodiments of the disclosure, power during standby may be further conserved, so as to better align with the standby specifications of the DRAM memory (such as the IDD2N specification).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A clock signal gating circuit, comprising:
a clock signal input buffer, receiving a clock signal and outputting an internal clock signal based on a clock switch signal;
a first logic circuit, receiving an asynchronous clock enable signal and a synchronous clock enable signal and outputting the clock switch signal;
a second logic circuit, receiving the asynchronous clock enable signal, the synchronous clock enable signal, and the internal clock signal and outputting a clock gating signal; and
a latch circuit, receiving the asynchronous clock enable signal and the clock gating signal to output the synchronous clock enable signal.

2. The clock signal gating circuit according to claim 1, wherein the second logic circuit outputs a high-level signal when the asynchronous clock enable signal and the synchronous clock enable signal are in different phases, and the second logic circuit outputs the clock gating signal during a period of outputting the high-level signal.

3. The clock signal gating circuit according to claim 1, wherein the first logic circuit is an OR gate.

4. The clock signal gating circuit according to claim 2, wherein the second logic circuit further comprises:
a phase comparison circuit, receiving and comparing a phase of the asynchronous clock enable signal and a phase of the synchronous clock enable signal and outputting the high-level signal when the phases are different; and
a switch, receiving an output of the phase comparison circuit and the internal clock signal and outputting the clock gating signal.

5. The clock signal gating circuit according to claim 4, wherein the phase comparison circuit is an XOR gate, and the switch is an AND gate.

6. The clock signal gating circuit according to claim 4, wherein when the phase comparison circuit outputs the high-level signal, the switch outputs the clock gating signal, which is the same as the internal clock signal, to the latch circuit.

7. The clock signal gating circuit according to claim 4, wherein when the phase comparison circuit outputs a low-level signal, the clock gating signal output by the switch to the latch circuit is halted.

8. The clock signal gating circuit according to claim 1, further comprising:
an input buffer, receiving a clock enable signal and a reference voltage signal to generate the asynchronous clock enable signal.

9. The clock signal gating circuit according to claim 8, wherein the input buffer converts the clock enable signal and output the asynchronous clock enable signal depending on whether a signal level of the reference voltage signal is high or low.

10. The clock signal gating circuit according to claim 8, wherein when the clock enable signal transitions to a high level, the asynchronous clock enable signal output by the input buffer activates the clock signal input buffer to output the internal clock signal.

11. The clock signal gating circuit according to claim 8, wherein upon a transition of the clock enable signal to a low level, the synchronous clock enable signal is generated through the latch circuit with a delay by a predetermined number of clock cycles.

12. The clock signal gating circuit according to claim 1, wherein the latch circuit delays the asynchronous clock enable signal by a predetermined number of clock cycles based on the asynchronous clock enable signal and the clock gating signal to generate the synchronous clock enable signal.

13. The clock signal gating circuit according to claim 1, wherein the clock signal comprises a pair of complementary clock signals.

14. The clock signal gating circuit according to claim 1, wherein the clock signal gating circuit is applied in a memory, and the memory is a dynamic random access memory.

15. The clock signal gating circuit according to claim 14, wherein the dynamic random access memory complies with a double data rate specification.
